(19) United States
(12) Patent Application Publication
(10) Pub. No.: US 2026/0243929 A1
(43) Pub. Date: Aug. 20, 2026

(54) SEAMLESS DISPLAY DEVICE

(71) Applicant: SAMSUNG ELECTRONICS CO., LTD., Suwon-si (KR)

(72) Inventors: Changkun LEE, Suwon-si (KR); Youngjin JO, Suwon-si (KR)

(73) Assignee: SAMSUNG ELECTRONICS CO., LTD., Suwon-si (KR)

(21) Appl. No.: 19/560,954

(22) Filed: Mar. 9, 2026

Related U.S. Application Data
(63) Continuation of application No. PCT/KR2026/002557, filed on Feb. 11, 2026.

(30) Foreign Application Priority Data
Feb. 11, 2025 (KR) 10-2025-0017514

(51) Int. Cl. G02B 5/04; H05K 5/30

(52) U.S. Cl. CPC G02B 5/045; H05K 5/30

(57) ABSTRACT

A seamless display device includes: a display accommodated in a panel accommodation structure and configured to output an image; an optical property conversion layer arranged above the display; and a geometric phase (GP) optical device arranged above the optical property conversion layer. The display includes: a first display configured to output a first image to the optical property conversion layer, where the optical property conversion layer is configured to polarize the first image to be left-circular polarized; and a second display configured to output a second image to the optical property conversion layer, where the optical property conversion layer is configured to polarize the second image to be right-circular polarized.

### CROSS-REFERENCE TO RELATED APPLICATIONS

This application is a Continuation Application of International Application PCT/KR2026/002557 filed on Feb. 11, 2026, which claims benefit of Korean Patent Application No. 10-2025-0017514, filed on Feb. 11, 2025, at the Korean Intellectual Property Office, the disclosures of which are incorporated herein in their entireties by reference.

### BACKGROUND

### 1. Field

The disclosure relates to a seamless display device. More particularly, the disclosure relates to a technique that uses a geometric phase (GP) optical device to make a seam or a bezel invisible at an edge portion of a panel included in a display.

### 2. Description of Related Art

Recently, the demand for display devices with large screens and high image-quality and three-dimensional (3D) display devices has been increasing. In order to realize a large-screen and high image-quality display device, the number of pixels arranged on a display may increase. Also, the number of pixels required for a 3D display device may be greater than the number of pixels required for a second-dimensional (2D) display device having the same resolution as the 3D display device. To represent a 3D image in a plurality of directions, a 3D display device may have a number of pixels corresponding to the number of pixels arranged in the 2D display device having the same resolution as the 3D display device multiplied by the number of directions in which the 3D image is represented.

The degree of integration for patterning pixels arranged on a display may be physically limited. Thus, it may not be easy to realize displays for display devices having a large screen with high image-quality or 3D display devices as a single panel. Accordingly, in order to realize a display device having a large screen with high image-quality and a 3D display device, a method of tiling a plurality of small-sized and high-resolution panels has been used.

When a plurality of small-sized and high-resolution panels are tiled to realize a large-screen for a high image-quality display device and a 3D display device, seams or bezels may be formed at edge portions at which the plurality of small-sized and high-resolution panels are connected to each other. Seams or bezels may be areas on which an image is not displayed. A user looking at a display device having a large screen with high image-quality or a 3D display device may feel a sense of difference when the seams or bezels are visible. Therefore, a technique may be required for reducing visibility of the seams or bezels formed when the plurality of small-sized and high-resolution panels are tiled.

### SUMMARY

Aspects will be set forth in part in the description which follows and, in part, will be apparent from the description, or may be learned by practice of the presented embodiments.

According to an aspect of the disclosure, a seamless display device may include: a display accommodated in a panel accommodation structure and configured to output an image; an optical property conversion layer arranged on the display; and a geometric phase (GP) optical device arranged on the optical property conversion layer.

According to an aspect of the disclosure, a seamless display device may include: a first display accommodated in a first panel accommodation structure and configured to output a first image; a second display accommodated in a second panel accommodation structure and configured to output a second image, wherein a bezel is provided between the first display and the second display; an optical property conversion layer provided on the first display and the second display and configured to polarize the first image and the second image in opposite directions; and a geometric phase (GP) optical device provided on the optical property conversion layer and configured to reflect an image outward from a position corresponding to the bezel.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1A is a diagram of a geometric phase (GP) optical device included in a seamless display device, according to an embodiment of the disclosure;

FIG. 1B is a diagram illustrating a characteristic of a GP optical device according to an embodiment of the disclosure;

FIG. 2 is a diagram illustrating a GP optical device that may control a path of light in order to display an image, according to an embodiment of the disclosure;

FIG. 3 is a diagram of a seamless display device according to an embodiment of the disclosure;

FIG. 4 is a diagram illustrating a seamless display device that may control a path of light, according to an embodiment of the disclosure;

FIG. 5 is a diagram illustrating a minimum angle of a path of light controlled by a GP optical device according to an embodiment of the disclosure;

FIG. 6 is a graph illustrating a period of a GP optical device according to a position of a seamless display device, according to an embodiment of the disclosure;

FIG. 7 is a diagram illustrating a seamless display device that may compensate for a color deviation, according to an embodiment of the disclosure;

FIG. 8 is a diagram illustrating a seamless display device that may compensate for a deviation in each direction, according to an embodiment of the disclosure;

FIG. 9 is a diagram of a seamless display device according to an embodiment of the disclosure;

FIG. 10 is a diagram of a seamless display device according to an embodiment of the disclosure;

FIG. 11 is a diagram of a seamless display device according to an embodiment of the disclosure;

FIG. 12 is a diagram of a projection unit of a seamless display device according to an embodiment of the disclosure;

FIG. 13 is a diagram of a holographic optical module including a plurality of projection units according to an embodiment of the disclosure;

FIG. 14 is a diagram of a holographic display of a seamless display device according to an embodiment of the disclosure;

FIG. 15 is a diagram illustrating equalization of brightness of a non-uniform display of a seamless display device according to an embodiment of the disclosure;

FIG. 16 is a diagram illustrating equalization of brightness of a non-uniform display of a seamless display device according to an embodiment of the disclosure; and

FIG. 17 is a diagram illustrating a seamless display device with no visible bezel, according to an embodiment of the disclosure.

### DETAILED DESCRIPTION

Various embodiments of the disclosure and terms used herein are not intended to limit the technical features described in this specification to particular embodiments of the disclosure, and it should be understood that various modifications, equivalents, or substitutes of the corresponding embodiments of the disclosure are also included in the technical features.

With regard to the description of the drawings, similar reference numerals may be used for similar or relevant components.

A singular form of a noun corresponding to an item may include a singular number or a plural number of the item, unless otherwise indicated in the context.

In this disclosure, each of expressions such as “A or B,” “at least one of A and B,” “at least one of A or B,” “A, B, or C,” “at least one of A, B, and C,” and “at least one of A, B, or C” may include any one of items listed together with the corresponding expression or all possible combinations of the same.

The expression “and/or” includes a combination of a plurality of described relevant components or any one of the plurality of described relevant components.

Terms such as “1st,” “2nd,” “first,” and “second” may be merely used to distinguish a corresponding component from other corresponding components and do not limit the corresponding components in terms of other aspects (for example, the degree of importance or the order).

When a certain (for example, a first) element is referred to as being “coupled” or “connected” to another (for example, a second) element with the term “functionally” or “communicatively” or without this term, the element may be connected to the other element directly (for example, in a wired manner), wirelessly, or through a third element.

The terms “including,” “having,” and “comprising” are used to indicate a presence of a feature, a number, a step, an operation, an element, a component, or a combination thereof described herein, and the terms do not exclude a presence of one or more other features, numbers, steps, operations, elements, components, or a combination thereof or the possibility of an addition of the same.

When a certain element is referred to as being “supported by” or “in contact with” another element, it denotes not only the case where the elements are directly supported by or in contact with each other, but also the case where the elements are indirectly supported by or in contact with each other through a third element.

When a certain element is referred to as being “above” or “on” another element, it includes not only the case where the element is in contact with the other element, but also the case where yet another element is present between the two components.

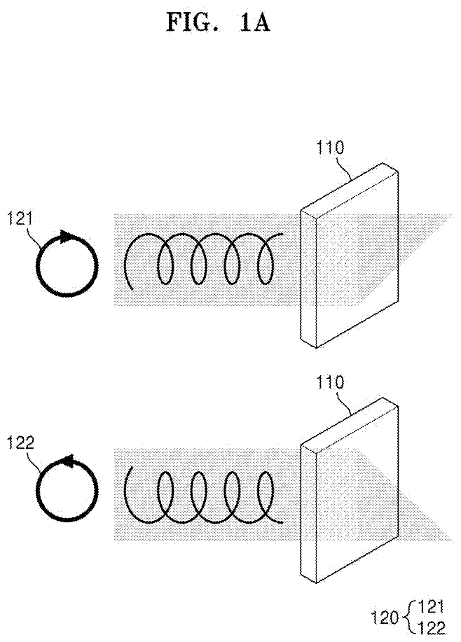

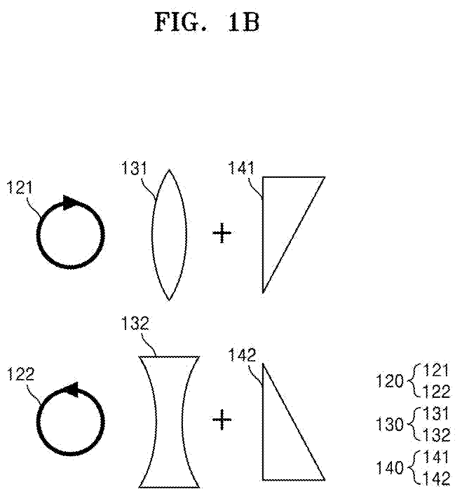

FIG. 1A is a diagram of a geometric phase (GP) optical device 110 included in a seamless display device according to an embodiment of the disclosure.

The GP optical device 110 may be a device configured to respond differently according to a polarization direction of light 120 incident thereon. The GP optical device 110 may be a device configured to control differently a proceeding direction of the light 120 incident thereon according to a polarization direction thereof. For example, when the incident light 120 is right-circular polarized light 121, the GP optical device 110 may control the proceeding direction of the incident light 120 in an upper direction. For example, when the incident light 120 is left-circular polarized light 122, the GP optical device 110 may control the proceeding direction of the incident light 120 in a lower direction. The GP optical device 110 may be used in various optical systems, such as a lens, a prism, and beam steering.

The GP optical device 110 may include a liquid crystal (LC). For example, the GP optical device 110 may arrange polymer liquid crystals in a flat shape, and through the arrangement of the liquid crystals, may differently control the proceeding direction of the incident light 120 according to the polarization direction thereof.

The GP optical device 110 may include an optical device using a Pancharatnam-Berry phase. By using the Pancharatnam-Berry phase, the GP optical device 110 may differently control the proceeding direction of the incident light 120 according to the polarization direction thereof.

The GP optical device 110 may include an optical device using a metasurface. By including the arranged nano-molecules, the GP optical device 110 may differently control the proceeding direction of the incident light 120 according to the polarization direction thereof.

FIG. 1B is a diagram illustrating a characteristic of the GP optical device 110 according to an embodiment of the disclosure.

The GP optical device 110 may have a characteristic in which a lens 130 and a prism 140 are coupled to each other. The GP optical device 110 may change a magnification of the incident light 120. The GP optical device 110 may change a proceeding direction of the incident light 120. The GP optical device 110 may change a phase of the incident light 120.

The GP optical device 110 may have a characteristic in which the lens 130 may have a different optical axis according to a polarization direction of the incident light 120. For example, when the incident light 120 is right-circular polarized light 121, the GP optical device 110 may have a characteristic of a convex lens 131. For example, when the incident light 120 is left-circular polarized light 122, the GP optical device 110 may have a characteristic of a concave lens 132.

The GP optical device 110 may have a characteristic in which the prism 140 has a different direction axis according to the polarization direction of the incident light 120. For example, when the incident light 120 is the right-circular polarized light 121, the GP optical device 110 may have a characteristic of a prism 141 having a direction axis inclined in an upper direction. For example, when the incident light 120 is the left-circular polarized light 122, the GP optical device 110 may have a characteristic of a prism 142 having a direction axis inclined in a lower direction.

The GP optical device 110 may have a characteristic in which a phase change may be different according to the polarization direction of the incident light 120. For example, when the incident light 120 is the right-circular polarized light 121, the GP optical device 110 may change the phase by QRCP. For example, when the incident light 120 is the left-circular polarized light 122, the GP optical device 110 may change the phase by QLCP. The relationship between ORCP and PLCP may be according to Equation 1.

$${φ}_{RCP} = - {φ}_{LCP} \qquad [ Equation 1 ]$$

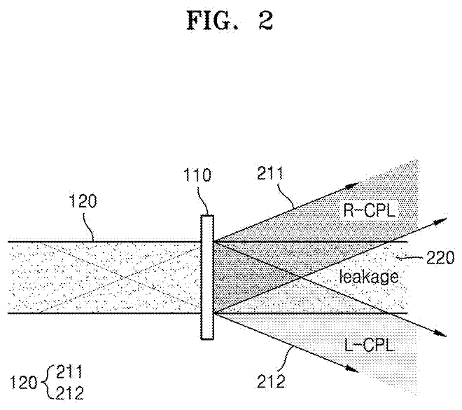

FIG. 2 illustrates the GP optical device 110 controlling a path of the light 120, according to an embodiment of the disclosure.

The GP optical device 110 may have a grating structure. The grating structure may diffract the incident light 120. The GP optical device 110 may change a proceeding direction of the incident light 120 through the grating structure.

The GP optical device 110 may change the proceeding direction of the incident light 120 to different directions, according to a polarization direction. The GP optical device 110 may make the light 120 proceed in a split way according to the polarization direction thereof. The GP optical device 110 may change the light 120 into polarized light 210 by transmitting the light 120. For example, the GP optical device 110 may change a proceeding direction of a right-circular polarized light component of the incident light 120 into an upper direction. For example, the GP optical device 110 may change a proceeding direction of a left-circular polarized light component of the incident light 120 into a lower direction. The light 120 transmitted through the GP optical device 110 may proceed by being split into the right-circular polarized light 211 proceeding in the upper direction and the left-circular polarized light 212 proceeding in the lower direction. A light component that is not polarized of the incident light 120 may become leakage light 220 proceeding outward from a surface of the GP optical device 110 with minimal or no change in direction.

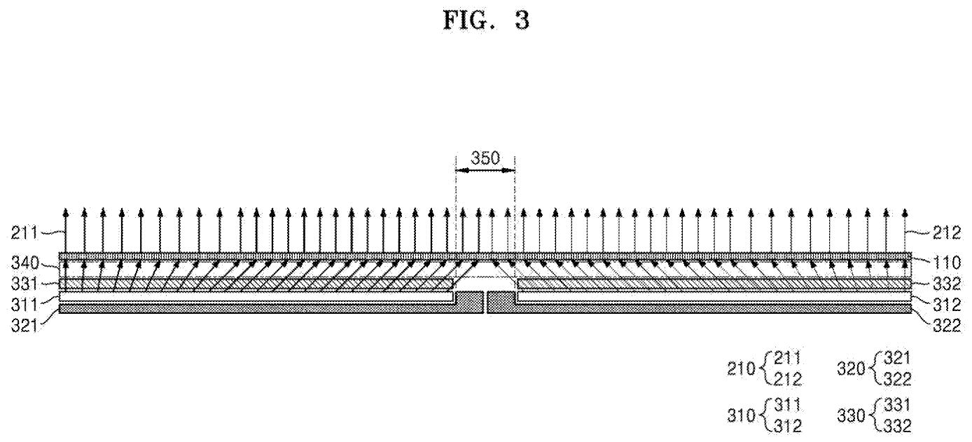

FIG. 3 is a diagram of a seamless display device according to an embodiment of the disclosure. The seamless display device according to an embodiment of the disclosure may include a display 310, an optical property conversion layer 330, and the GP optical device 110.

The display 310 may be accommodated in a panel accommodation structure 320. The panel accommodation structure 320 may support a lower portion and a side surface of the display 310. The display 310 may output an image 120. The image 120 may include light (e.g., the light 120 of FIGS. 1A, 1B, and 2), a still image, and a video image. The image 120 may be provided through the light 120, and thus will be described by using the same reference numeral as the light 120. The display 310 may include pixels for outputting the image 120.

The display 310 may include a first display 311 configured to output a first image 211 that is left-circular polarized by the optical property conversion layer 330 and a second display 312 configured to output a second image 212 that is right-circular polarized by the optical property conversion layer 330. According to an embodiment of the disclosure, the first image 211 may be provided through the left-circular polarized light 211, and thus will be described by using the same reference numeral as the left-circular polarized light 211 in FIG. 2. The second image 212 may be provided through the right-circular polarized light 212, and thus will be described by using the same reference numeral as the right-circular polarized light 212 in FIG. 2. The first display 311 may output an image linearly polarized in a first direction. The second display 312 may output an image linearly polarized in a second direction.

The optical property conversion layer 330 may be arranged above the display 310. The optical property conversion layer 330 may be arranged on the display 310. The optical property conversion layer 330 may include a first optical property conversion layer 331 arranged above the first display 311 and a second optical property conversion layer 332 arranged above the second display 312. The first optical property conversion layer 331 may be arranged on the first display 311 and the second optical property conversion layer 332 may be arranged on the second display 312. The optical property conversion layer 330 may transmit the image 120 incident from the display 310 in an upper direction. The optical property conversion layer 330 may convert an optical property of the image 120 that is incident. The optical property conversion layer 330 may convert a polarization direction of the image 120 that is incident. For example, the optical property conversion layer 330 may convert the image 120 that is linear polarized into an image 210 that is circular polarized. According to an embodiment of the disclosure, the image 210 may be provided through the polarized light 210, and thus will be described by using the same reference numeral as the polarized light 210.

The optical property conversion layer 330 may be configured to convert an optical property of the image 120 output from the display 310. For example, the optical property conversion layer 330 may be configured to convert a polarization type of the image 120 output from the display 310. For example, the optical property conversion layer 330 may be configured to convert a phase of the image 120 output from the display 310. For example, the optical property conversion layer 330 may be configured to delay the phase of the image 120 output from the display 310. The optical property conversion layer 330 may include a phase delay plate. For example, the optical property conversion layer 330 may include a quarter wave plate (QWP).

The GP optical device 110 may be arranged above the optical property conversion layer 330. The GP optical device 110 may change a proceeding direction of the image 210 that is circular polarized.

The GP optical device 110 may be arranged to be apart from the optical property conversion layer 330. A gap layer 340 may be arranged between the optical property conversion layer 330 and the GP optical device 110. The gap layer 340 may allow the GP optical device 110 to be apart from the optical property conversion layer 330 by a predetermined distance.

The GP optical device 110 may be provided as a single-layer structure. The GP optical device 110 may be provided as a single-layer structure to cover a first area in which the first display 311 is arranged and a second area in which the second display 312 is arranged.

The GP optical device 110 may control a path of the light 210 that is circular polarized, in order to display the image 120 to cover a bezel 350 between a first panel accommodation structure 321 and a second panel accommodation structure 322, which are included in the panel accommodation structure 320. The panel accommodation structure 320 may include the first panel accommodation structure 321 configured to accommodate the first display 311 and the second panel accommodation structure 322 configured to accommodate the second display 312. The bezel 350 may be formed between the first panel accommodation structure 321 and the second panel accommodation structure 322. The bezel 350 may be an area between the first display 311 and the second display 312, the area not displaying the image 120. The bezel 350 may be referred to as a seam. The GP optical device 110 may control the path of the light 210 that is circular polarized, such that it may seem that the image 120 is displayed on the bezel 350. For example, the GP optical device 110 may display the image 120 at an area corresponding to a position of the bezel 350. In this way, the bezel 350 may be covered by the image 120 so as to appear invisible or substantially invisible to a viewer.

The seamless display device according to an embodiment of the disclosure may optically cover the bezel 350 or the seam in the middle of the display 310 by using the GP optical device 110. The seamless display device according to an embodiment of the disclosure may fill the bezel 350, which is an empty space between the first display 311 and the second display 312, by varying the path of the light 210 by using the GP optical device 110 by applying different polarization directions to adjacent areas of the display 310.

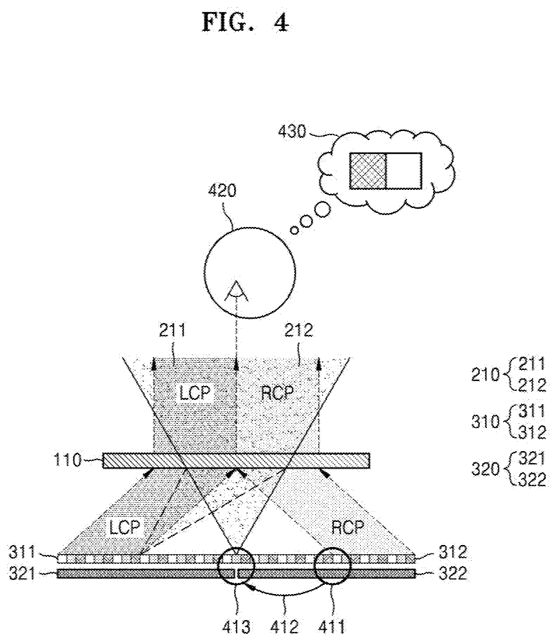

FIG. 4 is a diagram illustrating a seamless display device that may control a path of the light 210, according to an embodiment of the disclosure.

The seamless display device according to an embodiment of the disclosure may optically move a position of a pixel. By using the GP optical device 110, the seamless display device according to an embodiment of the disclosure may convert a proceeding direction of light, so that the pixel may seem to be arranged in a position different from an actual position. In other words, an apparent position of the pixel after proceeding from the GP optical device 110 is different from an actual position of the pixel on the display 310. For example, light output from a first pixel 411 arranged at an edge of the second display 312 may proceed based on a movement 412 to a central point 413 between the first display 311 and the second display 312. The light proceeding to the central point 413 between the first display 311 and the second display 312 may proceed in a direction perpendicular to a user 420 through the GP optical device 110. On a screen 430 visible to the user 420, the first pixel 411 may be seen as if the first pixel 411 is arranged on the central point 413.

The seamless display device according to an embodiment of the disclosure may not include a seam or an edge at the GP optical device 110 for removing the bezel 350, and thus, the user 420 may not see the bezel 350 or the seam. The user 420 may view the screen 430 including no bezel 350 or seam, through the seamless display device according to an embodiment of the disclosure.

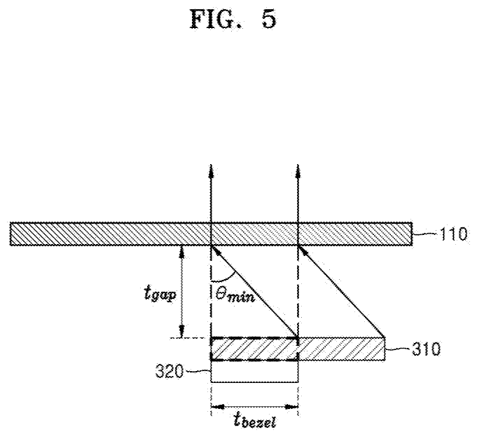

FIG. 5 is a diagram illustrating a minimum angle of a path of the light 120 controlled by the GP optical device 110 according to an embodiment of the disclosure.

In a seamless display device according to an embodiment of the disclosure, a minimum angle θₘᵢₙ by which the image 120 is incident onto the GP optical device 110 may correspond to a first thickness t_{bezel} of the bezel 350 and a second thickness t_{gap} of a gap between the display 310 and the GP optical device 110. For example, a minimum angle θₘᵢₙ by which the image 120 that is incident onto the GP optical device 110 is incident onto the GP optical device 110, may be determined based on a first thickness t_{bezel} of the bezel 350 and a second thickness t_{gap} of a gap between the display 310 and the GP optical device 110. The seamless display device may be realized by using the GP optical device 110, only when the image 120 is incident onto the GP optical device 110 by the minimum angle θₘᵢₙ. The minimum angle θₘᵢₙ may be according to Equation 2 below.

$${θ}_{min} > {tan}^{- 1} \frac{{t}_{gap}}{{t}_{bezel}} \qquad [ Equation 2 ]$$

In the seamless display device according to an embodiment of the disclosure, the minimum angle θₘᵢₙ may be determined according to the first thickness t_{bezel} of the bezel 350 and the second thickness t_{gap} of the gap. For example, when the first thickness t_{bezel} of the seamless display device has a designated value, the minimum angle θₘᵢₙ may be determined by adjusting the second thickness t_{gap}.

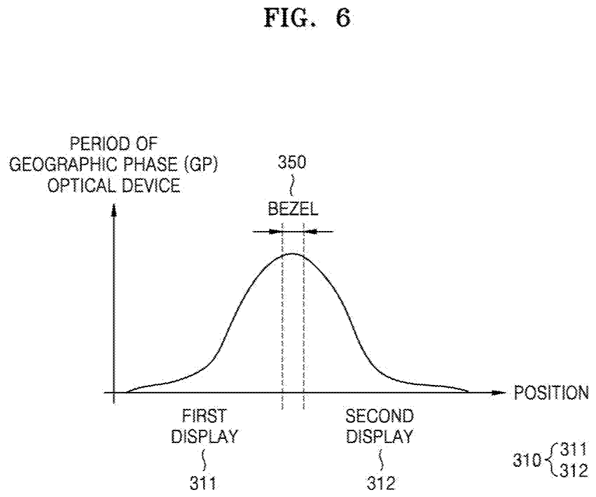

FIG. 6 is a graph showing a period of the GP optical device 110 according to a position of a seamless display device according to an embodiment of the disclosure.

The GP optical device 110 of the seamless display device according to an embodiment of the disclosure may have a period gradually changing according to a position of the display 310. The period of the GP optical device 110 may denote a section in which patterns in which molecules forming the GP optical device 110 are arranged are repeated. The period of the GP optical device 110 may change according to a molecule arrangement of the GP optical device 110. As the period of the GP optical device 110 increases, a proceeding direction of light incident onto the GP optical device 110 may change to an increased extent.

The period of the GP optical device 110 of the seamless display device according to an embodiment of the disclosure may be the highest at the bezel 350. The GP optical device 110 of the seamless display device according to an embodiment of the disclosure may set a highest period of the repetition of the patterns in which the molecules of the GP optical device 110 are arranged, at the position of the bezel 350. The GP optical device 110 of the seamless display device according to an embodiment of the disclosure may modulate the light incident onto the GP optical device 110 by a greatest angle, at the position of the bezel 350. The GP optical device 110 of the seamless display device according to an embodiment of the disclosure may reduce the period of the GP optical device 110 away from the bezel 350 toward an edge of the first display 311 and an edge of the second display 312. The GP optical device 110 of the seamless display device according to an embodiment of the disclosure may reduce the angle by which the light incident onto the GP optical device 110 is modulated, away from the bezel 350 toward an edge of the first display 311 and an edge of the second display 312.

The seamless display device according to an embodiment of the disclosure may gradually change the period of the GP optical device 110 and may control the proceeding direction of the light incident onto the GP optical device 110, so that the bezel 350 or the seam is not seen based on various shapes of the bezel 350 or the seam of the display 310 of the seamless display device. For example, the seamless display device according to an embodiment of the disclosure may control the proceeding direction of the light incident onto the GP optical device 110 such that both the seam in a horizontal direction and the seam in a vertical direction are not seen. The seamless display device according to an embodiment of the disclosure may gradually change the period of the GP optical device 110 and may control the proceeding direction of the light incident onto the GP optical device 110 such that the display 310 that is tiled is not seen, based on the number of tiled panels and a tiling direction of the display 310 of the seamless display device.

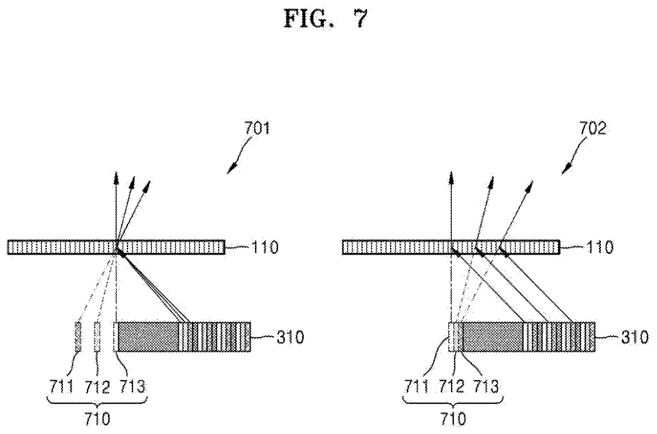

FIG. 7 is a diagram illustrating a seamless display device that may compensate for a color deviation, according to an embodiment of the disclosure.

The GP optical device 110 according to an embodiment of the disclosure may have a color deviation 701. The GP optical device 110 may have a different polarization characteristic according to each color 710. The GP optical device 110 may differently control a proceeding direction of light according to each color 710. For example, the GP optical device 110 may modulate the light by a different angle according to each color 710. The GP optical device 110 may differently control the proceeding direction of the light for each color 710 and may separate the light emitted from a pixel at the same position, based on each color 710. When the light emitted from the pixel at the same position is separated based on each color 710, the color deviation 701 may occur.

The seamless display device according to an embodiment of the disclosure may set a display position of the display 310 for each color 710 by reflecting a path of a light component differently proceeding for each color 10 according to the color deviation of the GP optical device 110. The seamless display device may measure a different color deviation profile for each color 710 of the GP optical device 110. The seamless display device may represent the original color 710 through compensation 702 for the color deviation using the measured color deviation profile.

The seamless display device according to an embodiment of the disclosure may perform the compensation 702 for the color deviation by separately changing, through image processing, each of images of a red color 711, a green color 712, and a blue color 713 included in the color 710. For example, the seamless display device may differently set lighting positions of pixels of the red color 711, the green color 712, and the blue color 713 included in the color 710 of the display 310. The seamless display device may adjust the lighting positions of the pixels of the red color 711, the green color 712, and the blue color 713 such that it may be seen by a user as if the red color 711, the green color 712, and the blue color 713 are displayed on the same position.

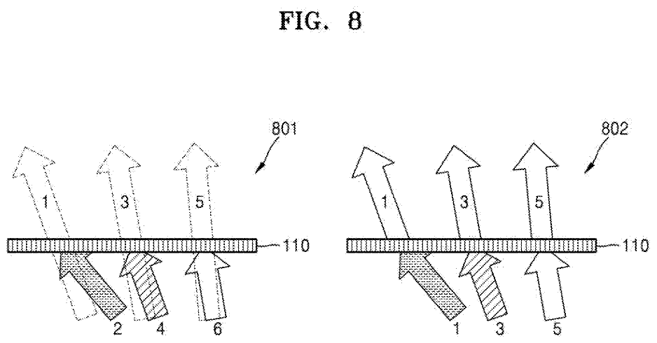

FIG. 8 is a diagram illustrating a seamless display device that may compensate for a deviation in each direction, according to an embodiment of the disclosure.

When the seamless display device displays a three-dimensional (3D) image, an image output by the display 310 may include direction information. For example, when the seamless display device is a light field display (LFD) or a holographic display, the display 310 may display a different image including different information for each direction.

The GP optical device 110 may have a deviation 801 for each direction when the GP optical device 110 controls a path of the image output by the display 310. The GP optical device 110 may set the path of the image in different directions according to an angle of incidence of the image. The GP optical device 110 may compensate for a deviation of an angle by which the image 120 is incident onto the GP optical device 110 for each direction to correspond to a direction in which the display 310 displays the image. When the path of the image is changed according to the angle of incidence of the image, the image may proceed in a direction different from an originally intended direction so that the direction information may be changed. For example, when number 2 direction information is changed to number 1 direction information, distortion of information in which an image different from an image originally intended by the display 310 to display is displayed may occur.

The seamless display device according to an embodiment of the disclosure may set a direction in which the display 310 displays an image, by performing, in advance, compensation 802 for a deviation for each direction of the GP optical device 110. The seamless display device may perform image processing of performing the compensation 802 in advance for the information for each direction by pre-calculating the deviation for each direction. For example, the seamless display device may perform the compensation 802 for the path of the image to an intended proceeding direction of the image in which the image is to be originally displayed, by shifting the pixel. For example, the seamless display device may perform the compensation 802 for the path of the image for each original image so that the image originally intended to be displayed may be normally displayed.

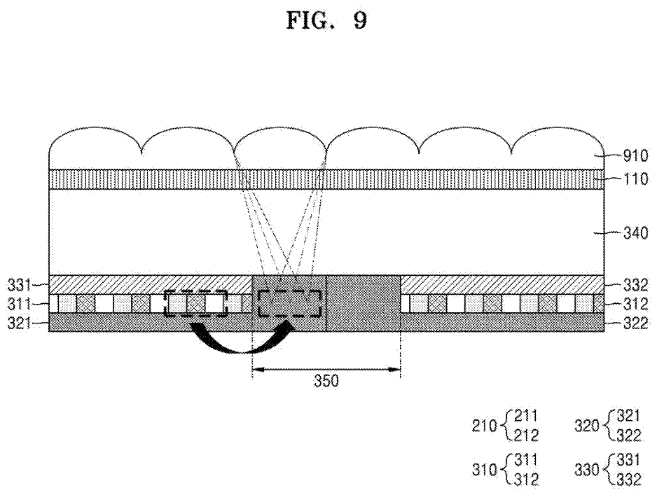

FIG. 9 is a diagram of a seamless display device according to an embodiment of the disclosure. The seamless display device according to an embodiment of the disclosure may include the display 310, the optical property conversion layer 330, the gap layer 340, the GP optical device 110, and a 3D image conversion layer 910.

The display 310 may be accommodated in the panel accommodation structure 320. The display 310 may include the first display 311 configured to output the first image 211 that is left-circular polarized by the optical property conversion layer 330 and the second display 312 configured to output the second image 212 that is right-circular polarized by the optical property conversion layer 330. The first display 311 may output an image linearly polarized in a first direction. The second display 312 may output an image linearly polarized in a second direction. The bezel 350 may be arranged between the first display 311 and the second display 312.

The optical property conversion layer 330 may be arranged above the display 310. The optical property conversion layer 330 may be arranged on the display 310. The optical property conversion layer 330 may include the first optical property conversion layer 331 arranged above the first display 311 and the second optical property conversion layer 332 arranged above the second display 312. The first optical property conversion layer 331 may be arranged on the first display 311 and the second optical property conversion layer 332 may be arranged on the second display 312. The optical property conversion layer 330 may convert an image that is linear polarized into an image that is circular polarized.

The gap layer 340 may be arranged between the optical property conversion layer 330 and the GP optical device 110. The gap layer 340 may allow the GP optical device 110 to be apart from the optical property conversion layer 330 by a predetermined distance.

The GP optical device 110 may be arranged above the optical property conversion layer 330. The GP optical device 110 may be arranged on the optical property conversion layer 330. The GP optical device 110 may change a proceeding direction of the image 210 that is circular polarized. The GP optical device 110 may optically move a pixel to a position at which the bezel 350 is located. The GP optical device 110 may change the path of the light 210 so that the pixel, rather than the bezel 350, may be seen.

The 3D image conversion layer 910 may convert a two-dimensional (2D) display screen into a 3D display screen. The 3D image conversion layer 910 may be a layer having a lens structure for providing a 3D effect to a user. For example, the 3D image conversion layer 910 may include a lenticular lens. The 3D image conversion layer 910 may be arranged above the GP optical device 110. The 3D image conversion layer 910 may be arranged on the GP optical device 110. The seamless display device according to an embodiment of the disclosure may display a 3D image by using the 3D image conversion layer 910.

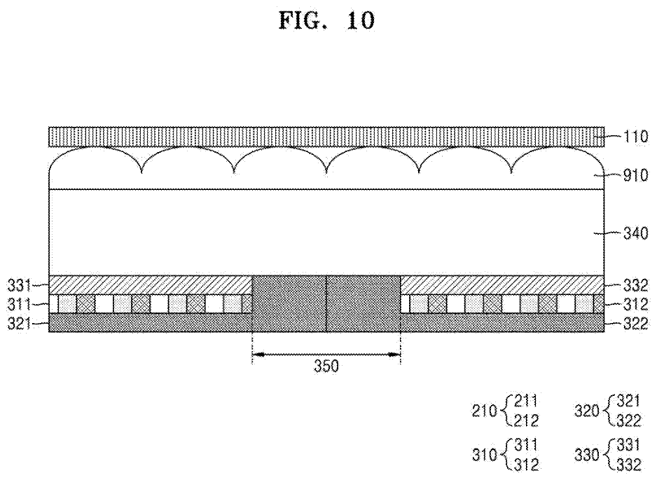

FIG. 10 is a diagram of a seamless display device according to an embodiment of the disclosure. The seamless display device according to an embodiment of the disclosure may include the display 310, the optical property conversion layer 330, the gap layer 340, the 3D image conversion layer 910, and the GP optical device 110.

The 3D image conversion layer 910 may be arranged between the optical property conversion layer 330 and the GP optical device 110. The GP optical device 110 may be arranged above the 3D image conversion layer 910. The GP optical device 110 may be arranged on the 3D image conversion layer 910. The 3D image conversion layer 910 may convert a 2D display screen into a 3D display screen. The GP optical device 110 may optically move a pixel to a position at which the bezel 350 is located.

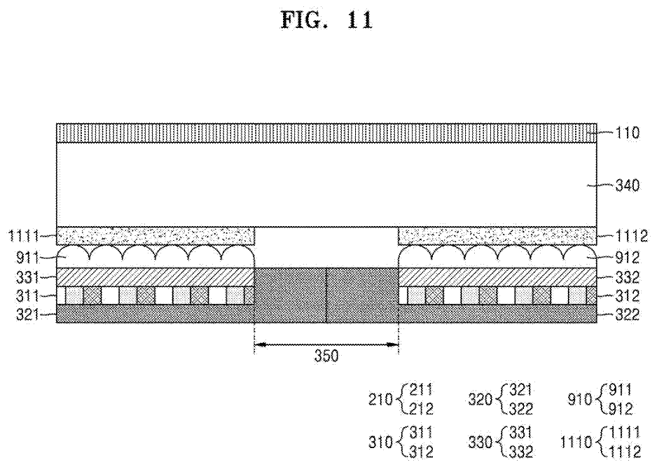

FIG. 11 is a diagram of a seamless display device according to an embodiment of the disclosure. The seamless display device according to an embodiment of the disclosure may include the display 310, the optical property conversion layer 330, the 3D image conversion layer 910, a polarization layer 1110, the gap layer 340, and the GP optical device 110.

The 3D image conversion layer 910 may be arranged between the optical property conversion layer 330 and the gap layer 340. The 3D image conversion layer 910 may include a first 3D image conversion layer 911 arranged above the first optical property conversion layer 331 and a second 3D image conversion layer 912 arranged above the second optical property conversion layer 332. The first 3D image conversion layer 911 may be arranged on the first optical property conversion layer 331 and the second 3D image conversion layer 912 may be arranged on the second optical property conversion layer 332. The 3D image conversion layer 910 may convert a 2D display screen into a 3D display screen.

The polarization layer 1110 may be arranged above the 3D image conversion layer 910. The polarization layer 1110 may be arranged on the 3D image conversion layer 910. The polarization layer 1110 may polarize light forming a 3D display, the light being transmitted through the 3D image conversion layer 910. The GP optical device 110 may optically move a pixel to a position at which the bezel 350 is located, with respect to the light forming the 3D display, the light being polarized by the polarization layer 1110.

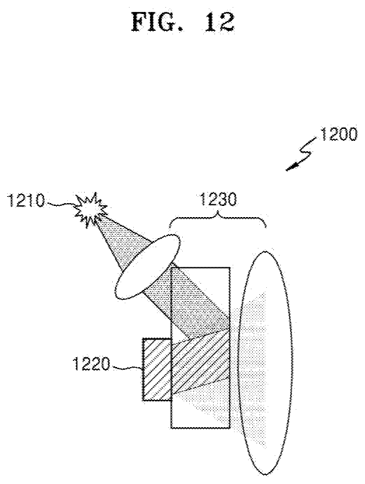

FIG. 12 is a diagram of a projection unit 1200 of a seamless display device according to an embodiment of the disclosure.

The seamless display device according to an embodiment of the disclosure may include at least one projection unit 1200 formed by using the display 310. The display 310 according to an embodiment of the disclosure may include at least one projection unit 1200. The projection unit 1200 may include a light source 1210, a display device 1220, and an optical component 1230.

The light source 1210 may be a source of light emitted to display a projection screen. The display device 1220 may be configured to project the light emitted from the light source 1210. The optical component 1230 may be an optical system configured to control a path of the projected light.

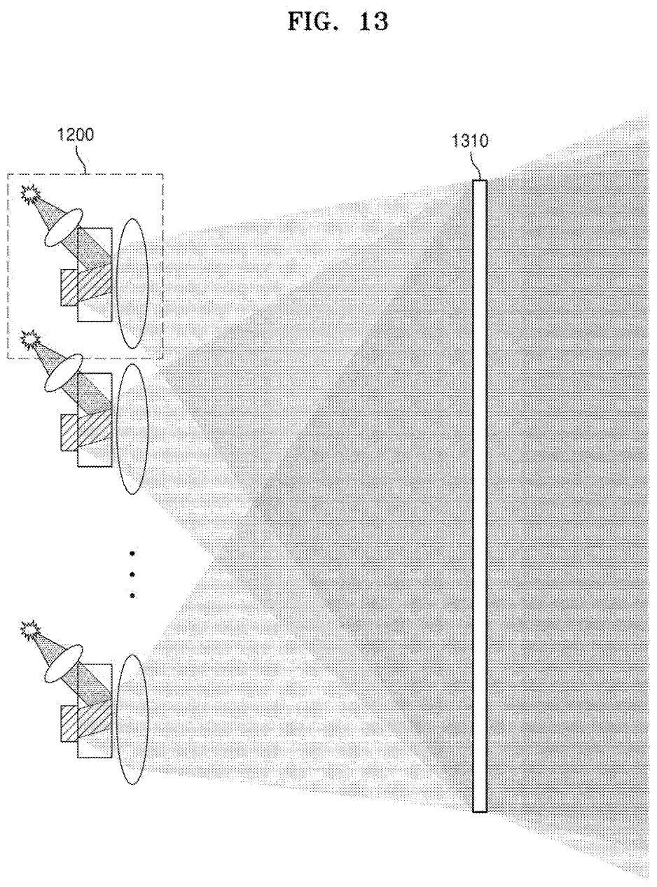

FIG. 13 is a diagram of a holographic optical module including a plurality of projection units 1200 according to an embodiment of the disclosure.

A seamless display device according to an embodiment of the disclosure may include a holographic optical module in which at least one projection unit 1200 is arranged in plurality and is projected in plurality on a holographic screen 1310. The display 310 according to an embodiment of the disclosure may include a holographic optical module in which a plurality of the projection units 1200 are arranged and projects the image onto a plurality of regions on a holographic screen 1310.

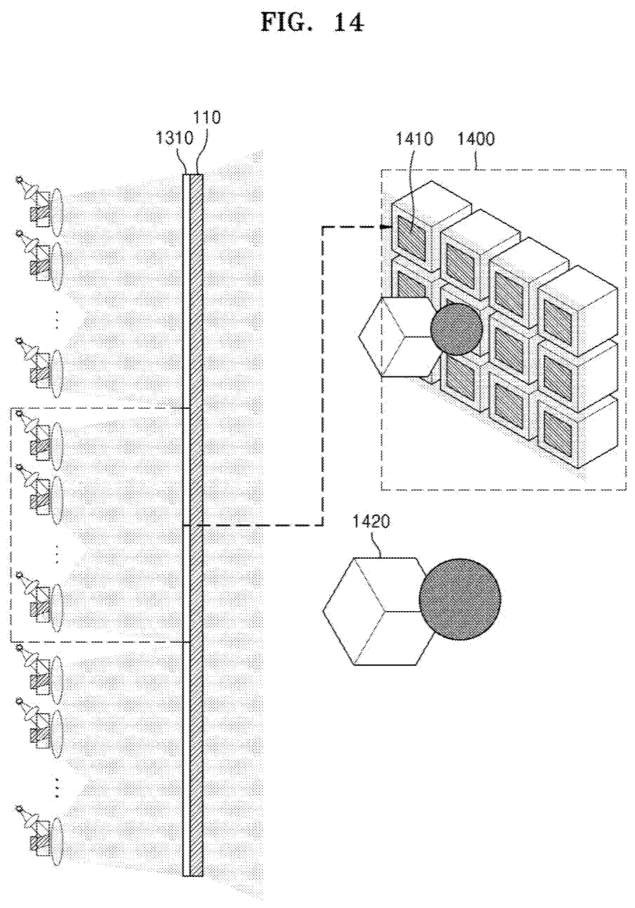

FIG. 14 is a diagram of a holographic display of a seamless display device according to an embodiment of the disclosure.

The seamless display device according to an embodiment of the disclosure may tile a holographic optical module 1400 into units 1410 and arrange the GP optical device 110 on a front side of the holographic optical module 1400. The holographic optical module 1400 may display a 3D image 1420. When the holographic optical module 1400 is tiled into the units 1410, a seam may be generated between the units 1410. When the GP optical device 110 is arranged on the front side of the holographic optical module 1400, the seam generated between the units 1410 may be removed.

The seamless display device according to an embodiment of the disclosure may arrange the GP optical device 110 on the front side of the holographic optical module 400 as a single layer. The GP optical device 110 may adjust a path in which an image incident from the holographic optical module 1400 proceeds. Thus, the GP optical device 110 may remove the seam generated between the units 1410 of the holographic optical module 1400.

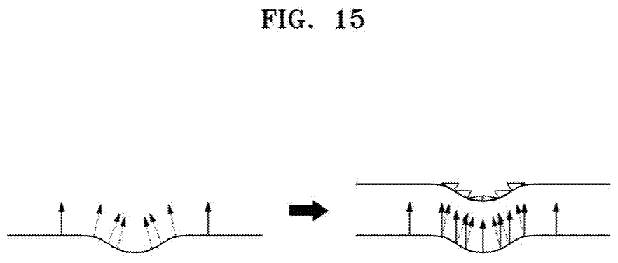

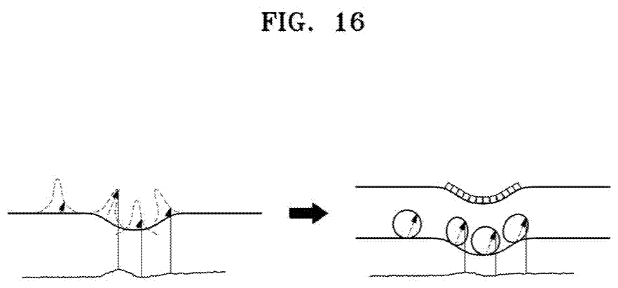

FIG. 15 is a diagram illustrating equalization of brightness of a non-uniform display of a seamless display device according to an embodiment of the disclosure. FIG. 16 is a diagram illustrating equalization of brightness of a non-uniform display of a seamless display device according to an embodiment of the disclosure.

The seamless display device according to an embodiment of the disclosure may configure the arrangement shape of the GP optical device 110 to correspond to a shape in which the display 310 emits the image 120. The seamless display device may gradually adjust a period of the GP optical device 110. When the period of the GP optical device 110 is gradually adjusted, the brightness of the non-uniform display 310 may be equalized.

The non-uniform display 310 may have a non-uniform structure to have a different brightness according to a position. For example, the display 310 may include at least one of a foldable display, a tiling display, a wall display, or a curved display. Display devices having various shapes are widely used. The seamless display device according to an embodiment of the disclosure may also be used in this case.

The seamless display device according to an embodiment of the disclosure may change an emission profile of a pixel included in the display 310 according to a shape of the display 310. According to the shape of the display 310, the brightness distribution of the display 310 may be changed. For example, according to a position at which a user views the display 310, the brightness distribution of the display 310 may be changed. For example, according to the change in the shape of the display 310, the brightness distribution of the display 310 may be changed. The seamless display device may reflect the change in the brightness distribution of the display 310 to the emission profile of the pixel.

The seamless display device according to an embodiment of the disclosure may determine an arrangement structure of the GP optical device 110, based on the emission profile of the pixel. For example, as illustrated in FIG. 15, the GP optical device 110 may include a plurality of micro-prism structures for gradually adjusting an optical axis. The micro-prism structures may shift the optical axis. The micro-prism structures may include a film having a thickness that is greater than or equal to about 10 μm and less than or equal to about 100 μm.

The seamless display device according to an embodiment of the disclosure may determine an optical property of the GP optical device 110, based on the emission profile of the pixel. For example, as illustrated in FIG. 16, the GP optical device 110 may include a plurality of Lambertian patterns for gradually adjusting an optical axis. The Lambertian patterns may planarize light as if the light is emitted from the display 310 in a flat shape, when the light emitted from the display 310 having a curved shape proceeds. The GP optical device 110 including the Lambertian patterns may locally adjust the optical axis. The GP optical device 110 including the Lambertian patterns may compensate for the emission profile of the pixel included in the display 310. The GP optical device 110 including the Lambertian patterns may have an in-cell structure patterned to the pixel included in the display 310.

The seamless display device according to an embodiment of the disclosure may finely segment the optical property by using the GP optical device 110. The seamless display device may control a profile of the pixel included in the display 310 by using the GP optical device 110. The seamless display device may inversely compensate for the emission profile of the pixel included in the display 310, by using the GP optical device 110.

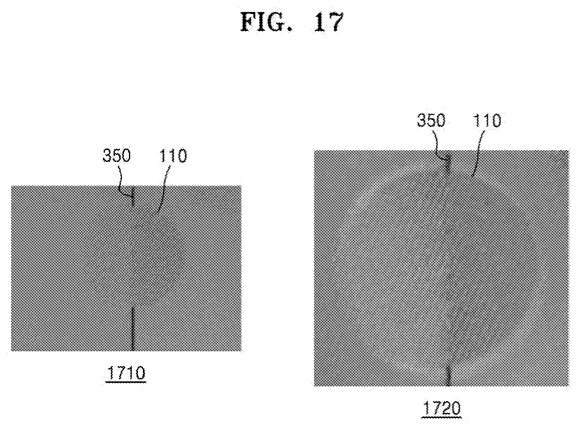

FIG. 17 is a diagram illustrating that the bezel 350 of a seamless display device is not seen, according to an embodiment of the disclosure.

The seamless display device according to an embodiment of the disclosure may make the bezel 350 not seen in both a 2D display 1710 and a 3D display 1720. By using the GP optical device 110, the seamless display device according to an embodiment of the disclosure may optically control a path of light as if a pixel of the 2D display 1710 or the 3D display 1720 is arranged at a portion at which the bezel 350 is arranged. The seamless display device according to an embodiment of the disclosure may cover the bezel 350 by using the GP optical device 110.

The disclosure provides a technique for reducing a physical seam which is generated when a method of tiling is applied in order to realize a large-screen display or a high-image quality 3D display.

A seamless display device according to the disclosure may include a display 310 accommodated in a panel accommodation structure 320 and configured to output an image 120, an optical property conversion layer 330 arranged above the display 310, and a GP optical device 110 arranged above the optical property conversion layer 330. The optical property conversion layer 330 may be provided on the display 310. The GP optical device 110 may be provided on the optical property conversion layer 330.

According to an embodiment of the disclosure, the display 310 may include a first display 311 configured to output a first image 211 left-circular polarized by the optical property conversion layer 330 and a second display 312 configured to output a second image 212 right-circular polarized by the optical property conversion layer 330.

According to an embodiment of the disclosure, the display 310 may include the first display 311 configured to output the first image 211 to the optical property conversion layer 330, wherein the optical property conversion layer 330 may be configured to polarize the first image 211 to be left-circular polarized. The display 310 may include the second display 312 configured to output the second image 212 to the optical property conversion layer 330, wherein the optical property conversion layer 330 may be configured to polarize the second image 312 to be right-circular polarized.

The seamless display device according to an embodiment of the disclosure may further include a gap layer 340 arranged between the optical property conversion layer 330 and the GP optical device 110.

According to an embodiment of the disclosure, the GP optical device 110 may be arranged in a single-layer structure.

According to an embodiment of the disclosure, the GP optical device 110 may be configured to control a path of circular polarized light 210 to display the image 120 to cover a bezel 350 between a first panel accommodation structure 321 and a second panel accommodation structure 322, which are included in the panel accommodation structure 320.

According to an embodiment of the disclosure, the panel accommodation structure 320 may include the first panel accommodation structure 321, the second panel accommodation structure 322, and the bezel 350 between the first panel accommodation structure 321 and the second panel accommodation structure 322. The GP optical device 110 may be configured to control a path of circular polarized light to display the image 210 over the bezel 350.

According to an embodiment of the disclosure, a minimum angle by which the image 120 incident onto the GP optical device 110 is incident onto the GP optical device 110 may be determined based on a first thickness of the bezel 350 and a second thickness of a gap between the display 310 and the GP optical device 110. According to an embodiment of the disclosure, the minimum angle by which the image 120 is incident onto the GP optical device 110 may correspond to a first thickness of the bezel 350 and a second thickness of a gap between the display 310 and the GP optical device 110.

According to an embodiment of the disclosure, the GP optical device 110 may have a period gradually changing according to a position of the display 310. The period of the GP optical device 110 may change according to a position of the display 310.

According to an embodiment of the disclosure, the period may be highest at the bezel 350. The period of the GP optical device 110 may be greatest at a position corresponding to the bezel 350.

The seamless display device according to an embodiment of the disclosure may set a display position of the display 310 for each color 710 by reflecting a path of a light component differently proceeding for each of the colors 710 according to a color deviation of the GP optical device 110. The GP optical device 110 may be configured to reflect a path of a light component differently for each color 710 according to a color deviation of the GP optical device 110.

The seamless display device according to an embodiment of the disclosure may compensate for a deviation for each direction of the GP optical device 110 in advance to set a direction in which the display 310 displays the image. The GP optical device 110 may be configured to compensate for a deviation of an angle by which the image 120 is incident onto the GP optical device 110 for each direction to correspond to a direction in which the display 310 displays the image 120.

The seamless display device according to an embodiment of the disclosure may further include a three-dimensional 3D image conversion layer 910 arranged above the GP optical device 110. The three-dimensional 3D image conversion layer 910 may be provided on the GP optical device 110

The seamless display device according to an embodiment of the disclosure may further include a 3D image conversion layer 910 arranged between the optical property conversion layer 330 and the GP optical device 110.

The seamless display device according to an embodiment of the disclosure may further include a 3D image conversion layer 910 arranged between the optical property conversion layer 330 and the gap layer 340 and a polarization layer 1110 arranged above the 3D image conversion layer 910. The polarization layer 1110 may be provided on the 3D image conversion layer 910.

The seamless display device according to an embodiment of the disclosure may further include at least one projection unit 1200 formed by using the display 310. According to an embodiment of the display 310 may include at least one projection unit 1200.

The seamless display device according to an embodiment of the disclosure may further include a holographic optical module 1400 in which the at least one projection unit 1200 is arranged in plurality and projected in plurality on a holographic screen 1310. According to an embodiment of the display 310 may include a holographic optical module 1400 including a plurality of the projection units 1200 and configured to project the image 120 onto a plurality of regions on a holographic screen 1310.

The seamless display device according to an embodiment of the disclosure may tile the holographic optical module 1400 into units 1410 and may arrange the GP optical device 110 on a front side of the holographic optical module 1400. According to an embodiment of the holographic optical module may be tiled into units, and the GP optical device may be provided on a front side of the holographic optical module.

The seamless display device according to an embodiment of the disclosure may set an arrangement shape of the GP optical device 110 to correspond to a shape in which the display 310 emits the image 120. The arrangement shape of the GP optical device 110 may correspond to the shape in which the display 310 emits the image 120.

According to an embodiment of the disclosure, the GP optical device 110 may include a plurality of micro-prism structures configured to gradually adjust an optical axis.

According to an embodiment of the disclosure, the GP optical device 110 may include a plurality of Lambertian patterns configured to gradually adjust an optical axis.

According to an embodiment of the disclosure, the display 310 may include at least one of a foldable display, a tiling display, a wall display, or a curved display.

According to an embodiment of the disclosure, a seamless display device may include a first display accommodated in a first panel accommodation structure and configured to output a first image; a second display accommodated in a second panel accommodation structure and configured to output a second image, wherein a bezel is provided between the first display and the second display; an optical property conversion layer provided on the first display and the second display and configured to polarize the first image and the second image in opposite directions; and a geometric phase (GP) optical device provided on the optical property conversion layer and configured to reflect an image outward from a position corresponding to the bezel.

The seamless display device according to the disclosure may realize a seamless display by effectively reducing seams by using a GP optical device having a simple structure with a small thickness and weight.

The method according to an embodiment of the disclosure may be implemented in the form of a program command executable by various computer devices and may be recorded on a computer-readable medium. The computer-readable medium may include a program command, a data file, a data structure, etc. individually or in a combined fashion. The program command recorded on the medium may be specially designed and configured for the disclosure or may be well known to and usable by one of ordinary skill in the art. Examples of the computer-readable recording medium include magnetic media (e.g., hard discs, floppy discs, or magnetic tapes), optical media (e.g., compact disc-read only memories (CD-ROMs), or digital versatile discs (DVDs)), magneto-optical media (e.g., floptical discs), and hardware devices that are specially configured to store and carry out program commands (e.g., ROMs, random-access memories (RAMs), or flash memories). Examples of the program commands include a high-level language code executable by a computer by using an interpreter, etc., as well as a machine language code, such as the one made by a complier.

One or more embodiments of the disclosure may also be realized in the form of a recording medium including instructions executable by a computer, such as a program module executed by a computer. A computer-readable medium may include an arbitrary available medium accessible by a computer and includes all of a volatile medium, a non-volatile medium, a detachable medium, and a non-detachable medium. Also, the computer-readable recording medium may include both of a computer storage medium and a communication medium. The computer storage medium may include all of a volatile medium, a non-volatile medium, a detachable medium, and a non-detachable medium realized by an arbitrary method or technique for storing a computer-readable instruction, a data structure, a program module, or information such as other data. The communication medium typically includes computer-readable instructions, data structures, program modules, or other data of modulated data signals, such as carrier waves, or other transmission mechanisms, and includes an arbitrary data transmission mechanism. Also, one or more embodiments of the disclosure may also be implemented by a computer program or a computer program product including a computer-executable instruction, such as a computer program executable by a computer.

Machine-readable storage media may be provided as non-transitory storage media. Here, the term “non-transitory storage medium” only denotes that a medium is a tangible device and does not include signals (e.g., electromagnetic waves), and the term does not distinguish a storage medium semi-permanently storing data and a storage medium temporarily storing data. For example, the “non-transitory storage medium” may include a buffer temporarily storing data.

According to an embodiment of the disclosure, the method according to various embodiments according to the disclosure may be provided as an inclusion of a computer program product. The computer program product may be transacted between a seller and a purchaser as a product. The computer program product may be distributed in the form of a machine-readable storage medium (e.g., CD-ROM) or may be distributed online (e.g., downloaded or uploaded) through an application store or directly between two user devices (e.g., smartphones). In the case of online distribution, at least part of a computer program product (e.g., a downloadable application) may be at least temporarily stored in a machine-readable storage medium, such as a server of a manufacturer, a server of an application store, or a memory of a relay server, or may be temporarily generated.

The above-described embodiments are merely specific examples to describe technical content according to the embodiments of the disclosure and help the understanding of the embodiments of the disclosure, not intended to limit the scope of the embodiments of the disclosure. Accordingly, the scope of various embodiments of the disclosure should be interpreted as encompassing all modifications or variations derived based on the technical spirit of various embodiments of the disclosure in addition to the embodiments disclosed herein.

1. A seamless display device comprising:
a display accommodated in a panel accommodation structure and configured to output an image;
an optical property conversion layer arranged above the display; and
a geometric phase (GP) optical device arranged above the optical property conversion layer.

2. The seamless display device of claim 1, wherein the display comprises:
a first display configured to output a first image to the optical property conversion layer, wherein the optical property conversion layer is configured to polarize the first image to be left-circular polarized; and
a second display configured to output a second image to the optical property conversion layer, wherein the optical property conversion layer is configured to polarize the second image to be right-circular polarized.

3. The seamless display device of claim 1, further comprising a gap layer between the optical property conversion layer and the GP optical device.

4. The seamless display device of claim 1, wherein the GP optical device is arranged in a single-layer structure.

5. The seamless display device of claim 1, wherein the panel accommodation structure comprises a first panel accommodation structure, a second panel accommodation structure, and a bezel between the first panel accommodation structure and the second panel accommodation structure,
wherein the GP optical device is configured to control a path of circular polarized light to display the image over the bezel.

6. The seamless display device of claim 5, wherein a minimum angle by which the image is incident onto the GP optical device corresponds to a first thickness of the bezel and a second thickness of a gap between the display and the GP optical device.

7. The seamless display device of claim 5, wherein a period of the GP optical device changes according to a position of the display.

8. The seamless display device of claim 7, wherein the period of the GP optical device is greatest at a position corresponding to the bezel.

9. The seamless display device of claim 1, wherein the GP optical device is configured to reflect a path of a light component differently for each color according to a color deviation of the GP optical device.

10. The seamless display device of claim 1, wherein the GP optical device is configured to compensate for a deviation of an angle by which the image is incident onto the GP optical device for each direction to correspond to a direction in which the display displays the image.

11. The seamless display device of claim 1, further comprising a three-dimensional (3D) image conversion layer arranged above the GP optical device.

12. The seamless display device of claim 1, further comprising a 3D image conversion layer between the optical property conversion layer and the GP optical device.

13. The seamless display device of claim 3, further comprising:
a 3D image conversion layer between the optical property conversion layer and the gap layer; and
a polarization layer arranged above the 3D image conversion layer.

14. The seamless display device of claim 1, wherein the display comprises at least one projection unit.

15. The seamless display device of claim 14, wherein the display further comprises a holographic optical module comprising a plurality of the projection units and configured to project the image onto a plurality of regions on a holographic screen.

16. The seamless display device of claim 15, wherein the holographic optical module is tiled into units, and the GP optical device is arranged on a front side of the holographic optical module.

17. The seamless display device of claim 1, wherein an arrangement shape of the GP optical device corresponds to a shape in which the display emits the image.

18. The seamless display device of claim 17, wherein the GP optical device comprises a plurality of micro-prism structures configured to adjust an optical axis.

19. The seamless display device of claim 17, wherein the GP optical device comprises a plurality of Lambertian patterns configured to adjust an optical axis.

20. A seamless display device comprising:
a first display accommodated in a first panel accommodation structure and configured to output a first image;
a second display accommodated in a second panel accommodation structure and configured to output a second image, wherein a bezel is provided between the first display and the second display;
an optical property conversion layer provided on the first display and the second display and configured to polarize the first image and the second image in opposite directions; and
a geometric phase (GP) optical device provided on the optical property conversion layer and configured to reflect an image outward from a position corresponding to the bezel.
